(19) United States
(12) Patent Application Publication
(10) Pub. No.: US 2023/0168220 A1
(43) Pub. Date: Jun. 1, 2023

(54) GAS SENSOR, SENSOR ELEMENT CONTAINMENT CASING, AND SEALING METHOD FOR USE IN SENSOR ELEMENT CONTAINMENT CASING

(71) Applicant: NGK INSULATORS, LTD., Nagoya-shi (JP)

(72) Inventors: Shintaro MAKI, Taketoyo-cho (JP); Kota KATAGIRI, Ginan-cho (JP); Yuya SEIKE, Nagoya-shi (JP); Kohei YAITA, Nagoya-shi (JP)

(21) Appl. No.: 17/994,221

(22) Filed: Nov. 25, 2022

(30) Foreign Application Priority Data
Nov. 30, 2021 (JP) 2021-194393

(51) Int. Cl. G01N 27/407

(52) U.S. Cl. CPC G01N 27/407; G01N 27/4078

(57) ABSTRACT

A gas sensor for sensing a predetermined gas component contained in a measurement gas includes: a sensor element including a sensing part on a side of one end portion thereof; and a casing in which the sensor element is contained and secured, including: an outer tube including a main portion in which a reference gas is present and into which the other end portion of the sensor element protrudes and a sealing portion being an end portion having a smaller diameter than the main portion; and a first seal member and a second seal member fit into the sealing portion in a two-tiered configuration to seal the outer tube, the first seal member is made of rubber, and the second seal member is made of resin more heat resistant than the first seal member, and is disposed closer to the sensor element than the first seal member is.

### CROSS-REFERENCE TO RELATED APPLICATIONS

The present application claims priority from Japanese application JP2021-194393, filed on Nov. 30, 2021, the contents of which is hereby incorporated by reference into this application.

### BACKGROUND OF THE INVENTION

### Field of the Invention

The present invention relates to a gas sensor and, in particular, to a structure of a casing for containing a sensor element.

### Description of the Background Art

As a device for measuring a concentration of a predetermined gas component in a measurement gas, such as a combustion gas and an exhaust gas from an internal combustion engine typified by an engine of a vehicle, a gas sensor including a sensor element formed of oxygen-ion conductive solid electrolyte ceramics, such as zirconia (ZrO₂), has been conventionally known.

As the gas sensor, a gas sensor having a configuration in which an elongated planar sensor element (detection element) including oxygen-ion conductive ceramics (e.g., yttria stabilized zirconia) as a main constituent material thereof is contained in a tubular containment member (casing) made of metal has widely been known (see Japanese Patent Application Laid-Open No. 2015-178988, for example). The gas sensor is attached along an exhaust path of the internal combustion engine, and is used to sense the predetermined gas component in the exhaust gas and to measure the concentration thereof.

One end portion of the casing has an opening, and a seal member made of rubber is fit into the opening. A protective cover through which the exhaust gas can enter and exit is attached to the other end portion of the casing. The sensor element is contained in the casing while a portion between the both end portions is sealed to be airtight. This allows one end portion of the sensor element to be in contact with a reference gas (typically, ambient air) in the casing on a side of the one end portion of the casing, and allows the other end portion of the sensor element to be exposed in the protective cover to be in contact with the exhaust gas on a side of the other end portion of the casing in the gas sensor. The reference gas and the exhaust gas are not in contact with each other.

The seal member made of rubber is fit into the opening of the casing after a lead for electrically connecting the sensor element to an outside is inserted into a through hole formed in advance, and the fit portion of the casing is swaged from a side part thereof together with the seal member to prevent ingress of water from outside through the opening.

The sensor element used for the gas sensor typically includes a heater for heating the oxygen-ion conductive ceramics to activate the oxygen-ion conductive ceramics. The gas sensor is thus at a high temperature when being in use not only due to heat transferred through piping and heat received from the exhaust gas generated with operation of the internal combustion engine but also due to heat generated by the heater of the gas sensor itself. Fluororubber, which is highly heat resistant, and the like are thus typically used for the seal member made of rubber.

Fluororubber, however, suffers from a drawback of outgassing when being at a high temperature. Outgassing causes contamination of the reference gas in the casing to reduce measurement accuracy of the gas sensor.

To address the problem, a gas sensor including the seal member having a two-tiered configuration in which a lower portion thereof has been replaced with silicon rubber having a low content of hazardous components with the intention of insulating the seal member made of rubber and a space in the casing in which the reference gas is present and suppressing the contamination of the reference gas caused by outgassing has already been known (see Japanese Patent Application Laid-Open No. 9-318580, for example).

There is a growing demand for shortening (reducing a length) of a gas sensor due to a narrowed component attachment space of the internal combustion engine in recent years. When responding to the demand by shortening the casing of the conventional gas sensor, the seal member made of rubber for closing the opening of the casing is brought close to piping or a heat source, such as the exhaust gas, in the piping. The seal member is thus required to be more heat resistant than the conventional seal member.

When the gas sensor is shortened while the two-tiered configuration disclosed in Japanese Patent Application Laid-Open No. 9-318580 is used, for example, a location at which the seal member made of silicon rubber is attached is brought closer to the heat source. The seal member made of silicon rubber, however, has a heat-resistant temperature approximately 20° C. lower than that of the seal member made of fluororubber, and thus has a high risk of heat deformation and erosion when the gas sensor is exposed to a high temperature environment with operation of the internal combustion engine.

Once heat deformation and erosion occur, gaps are formed in a surface of contact between the seal member made of silicon rubber and the casing and in the through hole of the seal member made of silicon rubber through which the lead is inserted, and gases generated from the seal member made of fluororubber similarly exposed to the high temperature environment flow into the casing through the gaps to cause contamination of the reference gas to thereby reduce measurement accuracy of the gas sensor.

### SUMMARY

The present invention is directed to a gas sensor and, in particular, to a configuration of a casing for containing a sensor element.

According to one aspect of the present invention, a gas sensor for sensing a predetermined gas component contained in a measurement gas includes: a sensor element including a sensing part on a side of one end portion thereof; and a casing in which the sensor element is contained and secured and which includes: an outer tube including a main portion in which a reference gas is present and a sealing portion being an end portion having a smaller diameter than the main portion; and a first seal member and a second seal member that seal the outer tube, wherein the other end portion of the sensor element protrudes into the main portion of the outer tube, the first seal member and the second seal member are fit into the sealing portion of the outer tube in a two-tiered configuration, the first seal member is made of rubber, and the second seal member is made of resin more heat resistant than the first seal member, and is disposed closer to the sensor element than the first seal member is.

According to another aspect of the present invention, as for a sealing method for sealing an end portion of an outer tube for use in a sensor element containment casing for containing a sensor element while securing the sensor element therein, the sensor element includes, on a side of one end portion thereof, a sensing part capable of sensing a predetermined gas component contained in a measurement gas, the end portion of the outer tube is sealed with the other end portion of the sensor element protruding into the outer tube, the sealing method includes: a) fitting the first seal member and the second seal member into the end portion tapered before being sealed while introducing a reference gas into the outer tube; and b) swaging a side of the end portion into which the first seal member and the second seal member have been fit from outside simultaneously at locations corresponding to the first seal member and the second seal member, the first seal member is made of rubber, and the second seal member is made of resin more heat resistant than the first seal member, and is disposed closer to the sensor element than the first seal member is in the step a).

According to the present invention, flow of gases generated from the seal member made of rubber into the external tube can suitably be suppressed in the gas sensor, so that reduction in measurement accuracy of the gas sensor can be prevented. Furthermore, the gas sensor can be shortened compared with a conventional gas sensor.

It is thus an object of the present invention to provide a gas sensor capable of responding to shortening while suitably suppressing flow of gases generated from a seal member into a casing.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a partial cross-sectional view along the length of a gas sensor 100;

FIG. 2 is a schematic plan view illustrating the layout of swaging jigs 1001 during securing by swaging;

FIG. 3 is a schematic side view illustrating securing by swaging using a swaging device 1000; and

FIG. 4 is a cross-sectional view along the length of a sensor element 10 for detecting NOx.

### DESCRIPTION OF THE PREFERRED EMBODIMENTS

<Configuration of Gas Sensor>

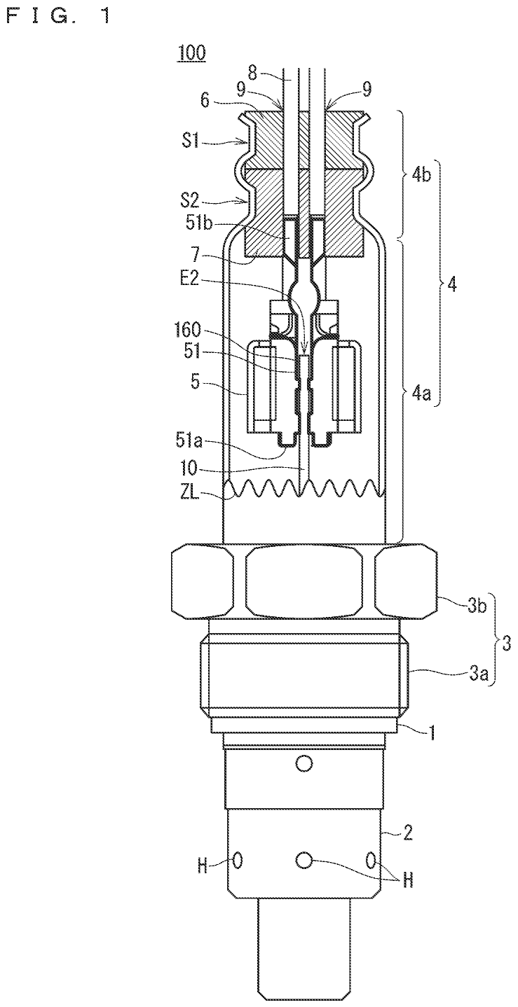

FIG. 1 is a partial cross-sectional view along a length of a gas sensor 100 (more particularly, a main body thereof) according to an embodiment of the present invention. More particularly, a cross-sectional view of the gas sensor 100 is illustrated above a break line ZL, and only appearance of the gas sensor 100 is illustrated below the break line ZL.

The gas sensor 100 is for detecting a predetermined gas component (e.g., NOx) using a sensor element 10 included therein. The gas sensor 100 generally has a configuration in which an elongated columnar or laminar sensor element (detection element) 10 is surrounded by a tubular body 1, a protective cover 2, a securing bolt 3, and an outer tube 4. The tubular body 1, the protective cover 2, and the outer tube 4 as a whole constitute a containment member (casing) for containing the sensor element 10 therein. On the other hand, the securing bolt 3 is fit around an outer side surface of the tubular body 1.

The sensor element 10 is disposed coaxially with the tubular body 1, the protective cover 2, the securing bolt 3, and the outer tube 4. A direction of extension of a central axis of the sensor element 10 is also referred to as an axial direction. In FIG. 1, the axial direction matches an up-down direction in FIG. 1.

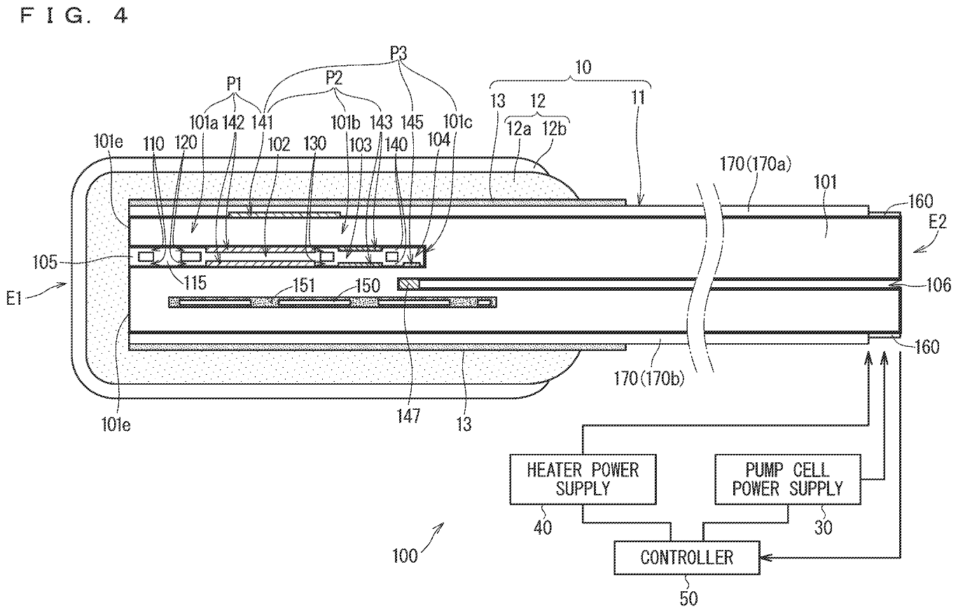

More particularly, one end portion (e.g., a first end portion E1 in FIG. 4) of the sensor element 10 is surrounded by the protective cover 2, the other end portion of the sensor element 10 protrudes into the outer tube 4, and a substantially middle portion between the end portions is secured in the tubular body 1 by an unillustrated ceramic green compact or ceramic component while being sealed to be airtight.

The sensor element 10 includes a sensing part (e.g., a gas inlet, an internal chamber, and a sensing electrode) on a side of the one end portion thereof surrounded by the protective cover 2. The sensor element 10 further includes various electrodes and wiring patterns on a surface of and in an element body thereof.

For example, in one aspect of the sensor element 10, a measurement gas introduced into the element is reduced or decomposed in the element to generate oxygen ions. The gas sensor 100 including the sensor element 10 having such a configuration determines the concentration of a gas component to be sensed in the measurement gas based on a quantity of oxygen ions flowing through the element proportional to the concentration of the gas component.

The tubular body 1 is a tubular member made of metal also referred to as a main metal fitting. The tubular body 1 is barely exposed to an outside of the gas sensor 100, and extends from an upper end portion in FIG. 1 of the protective cover 2 to a lower end portion in FIG. 1 of the outer tube 4. The sensor element 10 and a securing component (the ceramic green compact or the ceramic component) fit around the sensor element 10 are contained in the tubular body 1. In other words, the tubular body 1 is further fit around the fit component, which is fit around the sensor element 10.

The protective cover 2 is a substantially cylindrical exterior member for protecting a predetermined range on a side of the first end portion E1 of the sensor element 10 to be in direct contact with the measurement gas when being in use. The protective cover 2 is secured to a lower end portion in FIG. 1 of the tubular body 1 by welding.

The protective cover 2 has a plurality of through holes H through which gas can pass. The measurement gas flowing into the protective cover 2 through the through holes H is a direct sensing target of the sensor element 10. The types, the numbers, the locations, and the shapes of the through holes illustrated in FIG. 1 are just examples, and may be determined as appropriate in view of flow of the measurement gas into the protective cover 2.

The securing bolt 3 is an annular member used when the gas sensor 100 is secured to a measurement location. The securing bolt 3 includes a threaded bolt portion 3a and a holding portion 3b held when the bolt portion 3a is engaged. The bolt portion 3a engages with a nut disposed at an attachment location of the gas sensor 100. The gas sensor 100 is thereby secured at the measurement location with a side of the protective cover 2 thereof being in contact with a gas to be measured. For example, the bolt portion 3a engages with a nut portion disposed on an exhaust pipe of a vehicle so that the gas sensor 100 is secured to the exhaust pipe with the side of the protective cover 2 thereof being exposed in the exhaust pipe.

The outer tube 4 is a cylindrical member having one end portion (a lower end portion in FIG. 1) secured to an outer peripheral end portion of an unillustrated upper side of the tubular body 1 by welding. The outer tube 4 includes a main portion 4a extending from a part where the outer tube 4 is secured to the tubular body 1 by welding to have a constant diameter in the axial direction, and a sealing portion 4b contiguous with the main portion 4a in the axial direction. The sealing portion 4b is an end portion having a smaller diameter than the main portion 4a.

An internal space of the outer tube 4 is a reference gas (ambient air) atmosphere. A connector (also referred to as a contact point holding member) 5 is disposed in the main portion 4a.

On the other hand, the sealing portion 4b is a portion laterally swaged with a first seal member 6 and a second seal member 7 being fit into the sealing portion 4b to seal the other end portion (an upper end portion in FIG. 1) of the outer tube 4. The second seal member 7 is disposed closer to the sensor element 10 than the first seal member 6 is. Members for sealing the outer tube 4 are sometimes generically referred to as a grommet. That is to say, the outer tube 4 is sealed by a grommet having a two-tiered configuration.

The outer tube 4 is sealed by swaging an entire circumference of the sealing portion 4b in a first swaging portion S1 and a second swaging portion S2 respectively lateral to the first seal member 6 and the second seal member 7 in FIG. 1 so that the first seal member 6 and the second seal member 7 each generate radially outward reaction force. Sealing using the first seal member 6 and the second seal member 7 will be described in detail below.

The other end portion (e.g., a second end portion E2 in FIG. 4) of the sensor element 10 is inserted into the connector 5. The connector 5 includes a plurality of contact point members 51 made of metal to be in contact with a plurality of electrode terminals 160 (see FIG. 4) of the sensor element 10 when the sensor element 10 is inserted. One end portion (a lower end portion in FIG. 1) of each of the contact point members 51 is a hooked portion 51a hooked to the connector 5, the other end portion (an upper end portion in FIG. 1) of each of the contact point members 51 is a crimping portion 51b to which a lead 8 is secured by crimping, and a portion between the end portions is a leaf spring portion. The contact point members 51 are secured by being sandwiched between the connector 5 and the sensor element 10, so that the electrode terminals 160 of the sensor element 10 and the contact point members 51 are electrically connected.

Each of leads 8 is inserted into through holes 9 of the first seal member 6 and the second seal member 7, and has one end portion secured to the crimping portion 51b of the contact point member 51 by crimping and the other end portion connected to a controller 50 and various power supplies (see FIG. 4) outside the gas sensor 100. The sensor element 10 is thereby electrically connected to the controller 50 and the various power supplies through the contact point members 51 and the leads 8. While only two contact point members 51 and two leads 8 are illustrated in FIG. 1, they are for ease of illustration, and the required number of leads for electrical connection described above are actually provided.

<Sealing Using Seal Members>

Sealing of the outer tube 4 using the first seal member 6 and the second seal member 7 will be described in detail next.

As illustrated in FIG. 1, the first seal member 6 and the second seal member 7 are fit into the sealing portion 4b of the outer tube 4 in order from the top in FIG. 1 and secured by swaging. The first seal member 6 is made of rubber, and the second seal member 7 is made of resin, which is highly heat resistant. That is to say, materials of the first seal member 6 and the second seal member 7 are different.

The outer tube 4 is typically sealed using a single seal member (grommet) made of rubber in a conventional gas sensor, but the outer tube 4 is sealed using a configuration in which the conventional grommet has been partially replaced with a seal member made of resin in the gas sensor 100 according to the present embodiment.

The seal member being highly heat resistant in the present embodiment means that the seal member has a maximum continuous use temperature (a maximum temperature when use is continued at the maximum temperature) of approximately 260° C. or more. The second seal member 7 meets the requirement, whereas the first seal member 6 made of rubber does not meet the requirement, so that it can be said that the second seal member 7 is more heat resistant than the first seal member 6.

Rubber used for the first seal member 6 is typically fluororubber. Resin used for the second seal member 7 is preferably fluororesin, such as polytetrafluoroethylene (PTFE) and perfluoroalkoxy alkane (PFA), and is more preferably PTFE. PTFE has a maximum continuous use temperature of 260° C.

As described above, the gas sensor 100 is secured at the measurement location with the portion on the side of the protective cover 2 thereof being in contact with the gas to be measured when being in use. In addition, as will be described below, the sensor element 10 includes a heater (e.g., a heater 150 in FIG. 4), and the sensor element 10 is sometimes heated by the heater when the gas sensor 100 is in use. That is to say, the gas sensor 100 is typically at a higher temperature in a lower portion in FIG. 1 when being in use. In the gas sensor 100 according to the present embodiment, arrangement of the grommet that the second seal member 7 is disposed closer to the sensor element 10 than the first seal member 6 is as illustrated in FIG. 1 is for securing heat resistance according to the temperature distribution.

More particularly, the first seal member 6 made of rubber, such as fluororubber, has excellent adhesion to the outer tube 4, but might emit various outgases when heated to a high temperature. Flow of the outgases into the outer tube 4 (in particular, the main portion 4a thereof) causes contamination of the reference gas. The contamination is not preferable as it can reduce measurement accuracy of the gas sensor 100.

In the gas sensor 100 according to the present embodiment, however, the second seal member 7 made of resin more heat resistant than the first seal member 6 is disposed closer to the sensor element 10 than the first seal member 6 is, and is secured to the sealing portion 4b by swaging as with the first seal member 6, so that an increase in temperature of the first seal member 6 is suppressed even when a range from the protective cover 2 to the sensor element 10 is at a high temperature when the gas sensor 100 is in use, and the flow into the main portion 4a is suitably suppressed even when outgas sing from the first seal member 6 occurs.

In contrast to silicon rubber used for the seal member in the gas sensor disclosed in Japanese Patent Application Laid-Open No. 9-318580, resin used for the second seal member 7 is highly heat resistant, and is thus not deformed and eroded when the gas sensor 100 is in use.

In particular, in terms of PTFE as a preferred example of a material of the second seal member 7, outgassing therefrom at a high temperature is low, and thus the influence of the outgassing on the measurement accuracy of the gas sensor 100 is small. An effect of reducing outgassing can thus be obtained only by partially replacing a single seal member made of rubber with a seal member made of PTFE.

Furthermore, PTFE has a small gas permeability of 1/30 or less of that of silicon rubber, so that it can be said that a risk that outgases generated from the first seal member 6 might permeate the second seal member 7, and flow into the main portion 4a is sufficiently low, when the gas sensor 100 including the second seal member 7 made of PTFE is used for a long period of time.

A length of the second seal member 7 in the axial direction is preferably equal to or greater than a length of the first seal member 6 in the axial direction. In this case, heat resistance and an effect of suppressing the flow of the outgases of the second seal member 7 can suitably be obtained. Actual lengths of the first seal member 6 and the second seal member 7 may be set as appropriate according to the size of the gas sensor 100 as a whole, the size of the outer tube 4, the distance between the sensor element 10 and the first seal member 6 and the distance between the sensor element 10 and the second seal member 7, the temperature near the sealing portion 4b when the gas sensor 100 is in use, and the like.

Use of only the second seal member 7 without using the two-tiered configuration of the first seal member 6 and the second seal member 7, however, is not preferable in terms of securement of adhesion of the seal member to the outer tube 4.

The configuration used in the present embodiment in which the outer tube 4 is sealed using the grommet having the two-tiered configuration including the second seal member 7 being highly heat resistant is advantageous over the configuration of the conventional gas sensor in which the outer tube is sealed only using a single seal member (grommet) made of rubber, also in terms of shortening of the gas sensor 100. This is because, in the configuration according to the present embodiment, the second seal member 7 being heat resistant can be brought closer to a location closer to a high temperature heating region (heat source) where outgas sing of the seal member made of rubber occurs.

<Securing of Seal Members by Swaging>

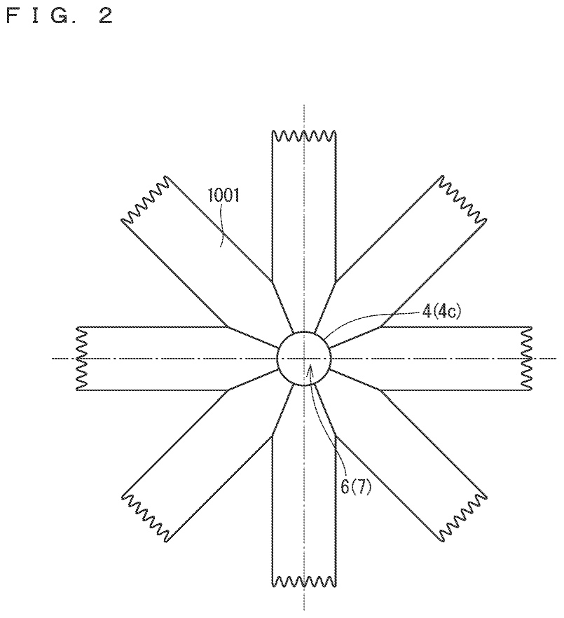

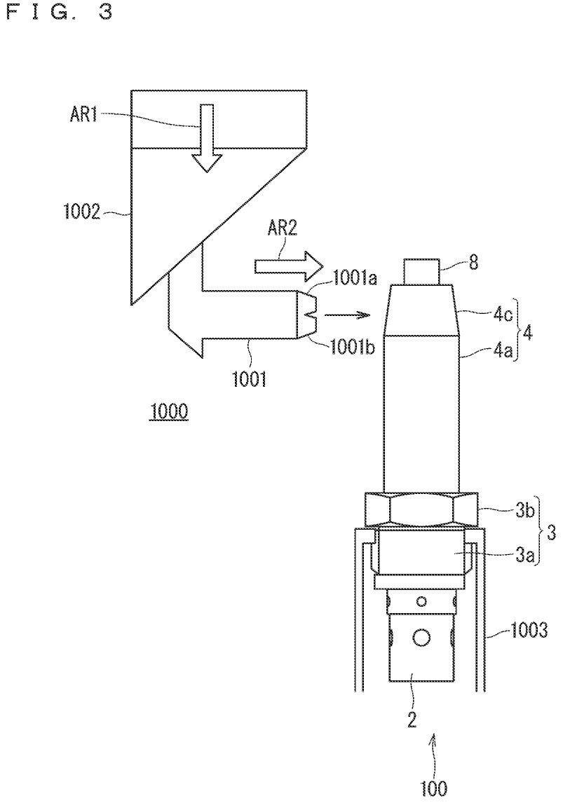

Securing of the first seal member 6 and the second seal member 7 by swaging to seal the outer tube 4 will be described next. FIG. 2 is a schematic plan view illustrating the layout of swaging jigs 1001 during securing by swaging. FIG. 3 is a schematic side view illustrating securing by swaging using a swaging device 1000. The sealing portion 4b of the outer tube 4 before securing by swaging is hereinafter particularly referred to as a pre-swaging sealing portion 4c. As illustrated in FIG. 3, the pre-swaging sealing portion 4c is tapered at a leading end thereof when viewed in cross section while being contiguous with the main portion 4a.

Securing by swaging is generally performed by simultaneously bringing the swaging jigs 1001 arranged isotropically (equiangularly) around the pre-swaging sealing portion 4c into contact with a side of the pre-swaging sealing portion 4c in a plane perpendicular to the axial direction as illustrated in FIG. 2.

While FIG. 2 illustrates a case where the entire circumference of the pre-swaging sealing portion 4c is continuously swaged using eight swaging jigs 1001 arranged at intervals of 45° in the plane perpendicular to the axial direction, this is just an example. The number of swaging jigs 1001 may be different, and a swaged portion may be discontinuous as long as good securing by swaging is achieved.

More particularly, prior to swaging, the connector 5 into which the sensor element 10 has been inserted and in which the contact point members 51 have been connected to the leads 8d is disposed in the main portion 4a of the outer tube 4 in advance. The first seal member 6 and the second seal member 7 are then fit into the pre-swaging sealing portion 4c while the leads 8 are inserted into the through holes 9. Swaging illustrated in FIG. 2 is performed on the gas sensor 100 in this state. Typically, ambient air as the reference gas has already entered the outer tube 4 before the first seal member 6 and the second seal member 7 are fit into the pre-swaging sealing portion 4c.

Securing by swaging is performed using the swaging device 1000 illustrated in FIG. 3. The swaging device 1000 includes the above-mentioned swaging jigs 1001, a plurality of lifting portions 1002 corresponding to the respective swaging jigs 1001, and a sensor support 1003 to which the gas sensor 100 targeted for securing by swaging is hooked. In FIG. 3, however, only one swaging jig 1001 and one lifting portion 1002 are illustrated for ease of illustration. Assume that an up-down direction in FIG. 3 is a vertical up-down direction.

The holding portion 3b that protrudes radially is hooked to the sensor support 1003 from above with the pre-swaging sealing portion 4c being directed vertically upward, so that the gas sensor 100 targeted for securing by swaging is supported by the sensor support 1003.

Each of the swaging jigs 1001 is horizontally moved as shown by an arrow AR2 to come into contact with the pre-swaging sealing portion 4c, with lowering of the corresponding lifting portion 1002 as shown by an arrow AR1. By lowering the lifting portions 1002 even after the contact, the swaging jigs 1001 press and deform the pre-swaging sealing portion 4c to form the sealing portion 4b having a cross section as illustrated in FIG. 1 and secure the first seal member 6 and the second seal member 7 to the sealing portion 4b.

Each of the swaging jigs 1001 is bifurcated to have a first contact portion 1001a and a second contact portion 1001b at a leading end thereof, and the first contact portion 1001a and the second contact portion 1001b simultaneously press the pre-swaging sealing portion 4c during securing by swaging. The first contact portion 1001a is brought into contact with a side of the first seal member 6 to form the first swaging portion S1 to secure the first seal member 6, and the second contact portion 1001b is brought into contact with a side of the second seal member 7 to form the second swaging portion S2 to secure the second seal member 7.

Heat resistance can be secured even when the grommet is swaged in a portion where the first seal member 6 is disposed while having the two-tiered configuration of the first seal member 6 and the second seal member 7. This, however, is disadvantageous in terms of a response to shortening of the gas sensor 100 because it is difficult to shorten the first seal member 6 due to the need to secure the swaging portion, and the overall length of the grommet increases by the length of the second seal member 7.

As described above, according to the present embodiment, the seal member of the gas sensor for sealing the end portion of the outer tube that surrounds a portion where the sensor element and the connector are connected and has a reference gas atmosphere therein has the two-tiered configuration of the seal member made of rubber and the seal member made of resin being highly heat resistant, the seal member made of resin is disposed closer to the portion that is at a high temperature when the gas sensor is in use than the seal member made of rubber is, and both the seal members are secured by swaging, which suitably suppress the flow of the outgases generated from the seal member made of rubber into the outer tube. Reduction in measurement accuracy of the gas sensor can thereby be prevented. The gas sensor can be shortened compared with a conventional gas sensor.

### Example of Configuration of Sensor Element

A configuration of the sensor element 10 for detecting NOx as an example of the sensor element 10 will finally be described. FIG. 4 is a cross-sectional view along the length of the sensor element 10 for detecting NOx. In this case, the sensor element 10 is a so-called limiting current type gas sensor element. FIG. 4 illustrates a pump cell power supply 30, a heater power supply 40, and the controller 50 of the gas sensor 100 in addition to the sensor element 10.

As illustrated in FIG. 4, the sensor element 10 generally has a configuration in which a portion of an elongated planar element base 11 on the side of the first end portion E1 is covered with a porous leading-end protective layer 12. The element base 11 includes an elongated planar ceramic body 101 as a main structure, and main-surface protective layers 170 (170a and 170b) are arranged on two main surfaces of the ceramic body 101. Furthermore, in the sensor element 10, the leading-end protective layer 12 (an inner leading-end protective layer 12a and an outer leading-end protective layer 12b) is disposed outside an end surface (a leading end surface 101e of the ceramic body 101) and four side surfaces on a side of one leading end portion.

In the present embodiment, end portions of the ceramic body 101 and the sensor element 10 on the side of the first end portion E1 of the element base 11 are also referred to as first end portions E1, and end portions of the ceramic body 101 and the sensor element 10 on a side of the second end portion E2 of the element base 11 are also referred to as second end portions E2 for the sake of convenience.

The ceramic body 101 is made of ceramics including, as a main component, zirconia (yttrium stabilized zirconia), which is an oxygen-ion conductive solid electrolyte. The ceramic body 101 is dense and airtight.

The sensor element 10 illustrated in FIG. 4 is a so-called serial three-chamber structure type gas sensor element including a first internal chamber 102, a second internal chamber 103, and a third internal chamber 104 inside the ceramic body 101. That is to say, in the sensor element 10, the first internal chamber 102 communicates, through a first diffusion control part 110 and a second diffusion control part 120, with a gas inlet 105 opening to the outside on the side of the first end portion E1 of the ceramic body 101 (to be precise, communicating with the outside through the leading-end protective layer 12), the second internal chamber 103 communicates with the first internal chamber 102 through a third diffusion control part 130, and the third internal chamber 104 communicates with the second internal chamber 103 through a fourth diffusion control part 140, in outline. A path from the gas inlet 105 to the third internal chamber 104 is also referred to as a gas distribution part. In the sensor element 10 according to the present embodiment, the distribution part is provided straight along the length of the ceramic body 101.

The first diffusion control part 110, the second diffusion control part 120, the third diffusion control part 130, and the fourth diffusion control part 140 are each provided as two slits vertically arranged in FIG. 4. The first diffusion control part 110, the second diffusion control part 120, the third diffusion control part 130, and the fourth diffusion control part 140 provide predetermined diffusion resistance to the measurement gas passing therethrough. A buffer space 115 having an effect of buffering pulsation of the measurement gas is provided between the first diffusion control part 110 and the second diffusion control part 120.

An outer pump electrode 141 is provided on an outer surface of the ceramic body 101, and an inner pump electrode 142 is provided in the first internal chamber 102. Furthermore, an auxiliary pump electrode 143 is provided in the second internal chamber 103, and a measurement electrode 145 as the sensing part for directly sensing a gas component to be measured is provided in the third internal chamber 104. In addition, a reference gas inlet 106 which communicates with the outside and through which the reference gas is introduced is provided on the side of the second end portion E2 of the ceramic body 101, and a reference electrode 147 is provided in the reference gas inlet 106.

In the gas sensor 100 including the sensor element 10, the concentration of a NOx gas in the measurement gas is calculated by a process as described below.

First, the measurement gas flowing into the protective cover 2 through the through holes H and introduced into the first internal chamber 102 through the gas inlet 105 is adjusted to have an approximately constant oxygen concentration by a pumping action (pumping in or out of oxygen) of a main pump cell P1, and then introduced into the second internal chamber 103. The main pump cell P1 is an electrochemical pump cell including the outer pump electrode 141, the inner pump electrode 142, and a ceramic layer 101a that is a portion of the ceramic body 101 present between these electrodes. In the second internal chamber 103, oxygen in the measurement gas is pumped out of the element by a pumping action of an auxiliary pump cell P2, which is also an electrochemical pump cell, so that the measurement gas is in a sufficiently low oxygen partial pressure state. The auxiliary pump cell P2 includes the outer pump electrode 141, the auxiliary pump electrode 143, and a ceramic layer 101b that is a portion of the ceramic body 101 present between these electrodes.

The outer pump electrode 141, the inner pump electrode 142, and the auxiliary pump electrode 143 are each formed as a porous cermet electrode (e.g., a cermet electrode made of ZrO₂ and Pt that includes Au of 1%). The inner pump electrode 142 and the auxiliary pump electrode 143 to be in contact with the measurement gas are each formed using a material having weakened or no reducing ability with respect to a NOx component in the measurement gas.

NOx in the measurement gas caused by the auxiliary pump cell P2 to be in a low oxygen partial pressure state is introduced into the third internal chamber 104, and reduced or decomposed by the measurement electrode 145 provided in the third internal chamber 104. The measurement electrode 145 is a porous cermet electrode also functioning as a NOx reduction catalyst that reduces NOx existing in an atmosphere in the third internal chamber 104. During the reduction or decomposition, a potential difference between the measurement electrode 145 and the reference electrode 147 is maintained constant. Oxygen ions generated by the above-mentioned reduction or decomposition are pumped out of the element by a measurement pump cell P3. The measurement pump cell P3 includes the outer pump electrode 141, the measurement electrode 145, and a ceramic layer 101c that is a portion of the ceramic body 101 present between these electrodes. The measurement pump cell P3 is an electrochemical pump cell pumping out oxygen generated by decomposition of NOx in an atmosphere around the measurement electrode 145.

Pumping (pumping in or out of oxygen) of the main pump cell P1, the auxiliary pump cell P2, and the measurement pump cell P3 is achieved, under control performed by the controller 50, by the pump cell power supply (variable power supply) 30 applying a voltage necessary for pumping across electrodes included in each of the pump cells. In a case of the measurement pump cell P3, a voltage is applied across the outer pump electrode 141 and the measurement electrode 145 so that the potential difference between the measurement electrode 145 and the reference electrode 147 is maintained at a predetermined value. The pump cell power supply 30 is typically provided for each pump cell.

The controller 50 detects a pump current Ip2 flowing between the measurement electrode 145 and the outer pump electrode 141 in accordance with the amount of oxygen pumped out by the measurement pump cell P3, and calculates a NOx concentration in the measurement gas based on a linear relationship between a current value (NOx signal) of the pump current Ip2 and the concentration of decomposed NOx.

The gas sensor 100 preferably includes a plurality of unillustrated electrochemical sensor cells sensing the potential difference between each pump electrode and the reference electrode 147, and each pump cell is controlled by the controller 50 based on a detected signal in each sensor cell.

In the sensor element 10, the heater 150 is buried in the ceramic body 101. The heater 150 is provided, below the gas distribution part in FIG. 4, over a range from the vicinity of the first end portion E1 to at least a location of formation of the measurement electrode 145 and the reference electrode 147. The heater 150 generates heat by being powered from the heater power supply 40 under control performed by the controller 50. The heater 150 is provided mainly to heat the sensor element 10 to enhance oxygen-ion conductivity of the solid electrolyte forming the ceramic body 101 when the sensor element 10 is in use. The sensor element 10 is heated so that the temperature at least in a range from the first internal chamber 102 to the second internal chamber 103 becomes 500° C. or more.

More specifically, the heater 150 is a resistance heating body made, for example, of platinum, and is provided to be surrounded by an insulating layer 151.

The plurality of electrode terminals 160 are formed on the respective main surfaces of the ceramic body 101 on the side of the second end portion E2 to establish electrical connection between the sensor element 10 and the outside. These electrode terminals 160 are electrically connected to the above-mentioned five electrodes, opposite ends of the heater 150, and unillustrated internal wiring for detecting heater resistance through unillustrated internal wiring provided within the ceramic body 101 to have a predetermined correspondence relationship. As described above, the electrode terminals 160 are connected to the leads 8 via the contact point members 51, and application of a voltage from the pump cell power supply 30 to each pump cell of the sensor element 10 and heating using the heater 150 by being powered from the heater power supply 40 are thus performed through the leads 8, the contact point members 51, and the electrode terminals 160.

The main-surface protective layers 170 are layers made of alumina, having a thickness of approximately 5 μm to 30 μm, and including pores with a porosity of approximately 20% to 40%, and are provided to prevent adherence of any foreign matter and poisoning substances to the two main surfaces of the ceramic body 101 and the outer pump electrode 141. The main-surface protective layer 170a thus functions as a pump electrode protective layer for protecting the outer pump electrode 141.

The leading-end protective layer 12 is provided around an outermost periphery of the element base 11 in a predetermined range from the first end portion E1. The leading-end protective layer 12 is provided in a manner of surrounding a portion of the element base 11 in which the temperature is high (up to approximately 700° C. to 800° C.) when the gas sensor 100 is in use, in order to ensure water resistance in the portion to thereby suppress the occurrence of cracking (water-induced breakage) of the element base 11 due to thermal shock caused by local temperature reduction upon direct exposure of the portion to water.

In addition, the leading-end protective layer 12 is provided to ensure poisoning resistance to prevent poisoning substances, such as Mg, from entering into the sensor element 10.

The inner leading-end protective layer 12a is made of alumina, has a porosity of 45% to 60%, and has a thickness of 450 μm to 650 μm. The outer leading-end protective layer 12b is made of alumina, has a porosity of 10% to 40%, which is lower than the porosity of the inner leading-end protective layer 12a, and has a thickness of 50 μm to 300 μm. The inner leading-end protective layer 12a is provided as a low thermal conductivity layer to have a function of suppressing thermal conduction from the outside to the element base 11.

The inner leading-end protective layer 12a and the outer leading-end protective layer 12b are formed by sequentially thermal spraying (plasma-spraying) constituent materials thereof with respect to the element base 11 having the surface on which an underlying layer 13 has been formed.

As illustrated in FIG. 4, the underlying layer 13 is provided between the inner leading-end protective layer 12a and the element base 11 to secure adhesion of the inner leading-end protective layer 12a. The underlying layer 13 is provided at least on the two main surfaces of the element base 11. The underlying layer 13 is made of alumina, has a porosity of 30% to 60%, and has a thickness of 15 μm to 50 μm.

<Modifications>

While the limiting current type sensor element having three internal chambers and detecting NOx as a gas component to be detected is shown as an example of the sensor element 10 in the above-mentioned embodiment, the number of internal chambers may not be three and a gas component other than NOx may be detected in the sensor element 10 of the gas sensor 100. Alternatively, the sensor element may be a sensor element having no internal chambers, such as a mixed potential type sensor element.

### EXAMPLES

### Example 1

The amount of outgassing of each of resin used for the second seal member 7 and rubber used for a conventional seal member (conventional product) was evaluated. PTFE having a diameter of 11 mm and a thickness of 3 mm was prepared as the resin, and fluororubber having a diameter of 11 mm and a thickness of 14 mm was prepared as the rubber.

An analysis by thermal desorption gas chromatography was conducted after the surface was shaved. A heating temperature range was room temperature to 280° C., a heating atmosphere was nitrogen, and a sample weight was 90 mg.

The detected amount of outgas sing of each of them is shown in Table 1.

TABLE 1

| | CONVENTIONAL PRODUCT |
|---|---|
| PTFE | (FLUORORUBBER) |
| 6.77 [ng] | 402.68 [ng] |

As can be seen from Table 1, the amount of outgassing of PTFE was approximately 1/60 of that of fluororubber. The result suggests that the flow of the gases generated from the seal member made of rubber can suitably be suppressed by replacing a portion of the seal member made of rubber with the seal member made of resin as in the above-mentioned embodiment compared with a case where only the seal member made of rubber is used.

### Example 2

As for the gas sensor 100 (hereinafter also referred to as an invented product) including the sensor element 10 as a NOx sensor and as a gas sensor according to an example, the influence of outgassing of the first seal member 6 on the measurement accuracy was evaluated. The first seal member 6 was made of fluororubber, and the second seal member 7 was made of PTFE.

As a gas sensor according to a comparative example (hereinafter also referred to as a conventional product), a gas sensor having the same configuration as the gas sensor according to the example except that a single seal member (grommet) made of fluororubber was used in place of the grommet having the two-tiered configuration of the first seal member 6 and the second seal member 7, and the outer tube 4 was lengthened in the axial direction to locate the seal member farther away than the seal member according to the example was prepared, and similarly evaluated.

Specifically, four gas sensors were prepared for each of the example and the comparative example, the pump current Ip2 was measured for each of the gas sensors while the gas sensor was heated using a burner testing machine, and the measurement accuracy of the gas sensor was evaluated based on stability thereof.

More particularly, in order to meet the same outgassing condition, the gas sensors according to the example and the gas sensors according to the comparative example were heated so that the temperature of the first seal member 6 of each of the gas sensors according to the example and the temperature of the seal member of each of the gas sensors according to the comparative example each made of fluororubber were 280° C. Outgassing of the seal member made of fluororubber heated to 280° C. has been observed in advance. Heating the first seal member 6 to 280° C. in each of the gas sensors according to example means that the second seal member 7 is heated to a temperature higher than 280° C. Heating was performed until 80 minutes had elapsed since the start of elevation of the temperature.

After the start of heating to the elevated temperature, each of the gas sensors was driven, and then measurement of the pump current Ip2 was started. An average value μ and a standard deviation σ of the pump current Ip2 from a time point when three minutes had elapsed since the start of driving of each of the gas sensors to a time point when the temperature of the grommet reached 250° C. were determined, and the average value μ and the standard deviation σ were used as indices of evaluation of the measurement accuracy.

Specifically, when the pump current Ip2 fell within a range of μ±4σ from a timing the temperature of the grommet reached 250° C. until an end of the test after the elapse of 90 minutes since the start of elevation of the temperature, it was evaluated that the measurement accuracy of the gas sensor has not been reduced. A deviation of the pump current Ip2 from the range during the elevation of the temperature was removed from determination, as the deviation was presumably caused by adherence of any foreign matter to the gas sensor.

On the other hand, when the pump current Ip2 fell outside the range of μ+4σ at the end of the test, it was evaluated that the measurement accuracy of the gas sensor has been reduced.

A result of evaluation of each of the gas sensors according to the example (invention) and the gas sensors according to the comparative example (conventional product) is shown in Table 2.

TABLE 2

SAMPLE NO

| | 1 | 2 | 3 | 4 |
|---|---|---|---|---|
| CONVENTIONAL PRODUCT | x | x | x | x |
| INVENTED PRODUCT | ∘ | ∘ | ∘ | ∘ |

∘: MEASUREMENT ACCURACY WAS NOT REDUCED,
x: MEASUREMENT ACCURACY WAS REDUCED

As can be seen from Table 2, reduction in measurement accuracy was not observed in each of the gas sensors according to the example. On the other hand, reduction in measurement accuracy was observed in each of the gas sensors according to the comparative example.

Outgas sing of the seal member made of fluororubber occurred in each of the gas sensors, so that the difference in results between the example and the comparative example suggests that use of the two-tiered configuration in the above-mentioned embodiment for the grommet of the gas sensor suitably suppresses outgassing of fluororubber, and thus reduction in measurement accuracy of the gas sensor due to the flow of the gases into the outer tube is suitably suppressed. The difference also suggests that outgassing of a sealing member made of resin itself rarely occurs.

In addition, the difference suggests that the sealing member made of resin being highly heat resistant can be disposed at the location closer to the high temperature heating region (heat source) where outgas sing of a conventional sealing member made of rubber occurs.

While the invention has been shown and described in detail, the foregoing description is in all aspects illustrative and not restrictive. It is therefore understood that numerous modifications and variations can be devised without departing from the scope of the invention.

What is claimed is:

1. A gas sensor for sensing a predetermined gas component contained in a measurement gas, the gas sensor comprising:
a sensor element including a sensing part on a side of one end portion thereof; and
a casing in which the sensor element is contained and secured, the casing including:
an outer tube including a main portion in which a reference gas is present and a sealing portion being an end portion having a smaller diameter than the main portion; and
a first seal member and a second seal member that seal the outer tube, wherein
the other end portion of the sensor element protrudes into the main portion of the outer tube,
the first seal member and the second seal member are fit into the sealing portion of the outer tube in a two-tiered configuration,
the first seal member is made of rubber, and
the second seal member is made of resin more heat resistant than the first seal member, and is disposed closer to the sensor element than the first seal member is.

2. The gas sensor according to claim 1, wherein
the first seal member is made of fluororubber, and
the second seal member is made of fluororesin.

3. The gas sensor according to claim 2, wherein
the second seal member is made of PTFE.

4. The gas sensor according to claim 1, wherein
the main portion extends in an axial direction of the sensor element, and
a length of the second seal member in the axial direction is equal to or greater than a length of the first seal member in the axial direction.

5. The gas sensor according to claim 1, wherein
a side of the sealing portion has been swaged from outside at locations corresponding to the first seal member and the second seal member to seal the outer tube.

6. The gas sensor according to claim 5, wherein
an entire side circumference of the sealing portion has been swaged at the locations corresponding to the first seal member and the second seal member.

7. A sensor element containment casing for containing a sensor element while securing the sensor element therein, the sensor element including, on a side of one end portion thereof, a sensing part for sensing a predetermined gas component contained in a measurement gas, the sensor element containment casing comprising:
an outer tube including a main portion in which a reference gas is present and a sealing portion being an end portion having a smaller diameter than the main portion; and
a first seal member and a second seal member that seal the outer tube, wherein
the outer tube is disposed so that the other end portion of the sensor element protrudes into the main portion,
the first seal member and the second seal member are fit into the sealing portion of the outer tube in a two-tiered configuration,
the first seal member is made of rubber, and
the second seal member is made of resin more heat resistant than the first seal member, and is disposed closer to the sensor element than the first seal member is.

8. The sensor element containment casing according to claim 7, wherein
the first seal member is made of fluororubber, and
the second seal member is made of fluororesin.

9. The sensor element containment casing according to claim 8, wherein
the second seal member is made of PTFE.

10. The sensor element containment casing according to claim 7, wherein
an axial direction of the sensor element matches a direction of extension of the main portion when the sensor element is contained, and
a length of the second seal member in the direction of extension is equal to or greater than a length of the first seal member in the direction of extension.

11. The sensor element containment casing according to claim 7, wherein
a side of the sealing portion has been swaged from outside at locations corresponding to the first seal member and the second seal member to seal the outer tube.

12. The sensor element containment casing according to claim 11, wherein
an entire side circumference of the sealing portion has been swaged at the locations corresponding to the first seal member and the second seal member.

13. A sealing method for sealing an end portion of an outer tube in a sensor element containment casing for containing a sensor element while securing the sensor element therein, wherein
the sensor element includes, on a side of one end portion thereof, a sensing part capable of sensing a predetermined gas component contained in a measurement gas,
the end portion of the outer tube is sealed with the other end portion of the sensor element protruding into the outer tube,
the sealing method comprises:
a) fitting the first seal member and the second seal member into the end portion tapered before being sealed while introducing a reference gas into the outer tube; and
b) swaging a side of the end portion into which the first seal member and the second seal member have been fit, from outside simultaneously at locations corresponding to the first seal member and the second seal member,
the first seal member is made of rubber, and
the second seal member is made of resin more heat resistant than the first seal member, and is disposed closer to the sensor element than the first seal member is in the step a).

14. The sealing method for use in the sensor element containment casing according to claim 13, wherein
an entire side circumference of the end portion is swaged at the locations corresponding to the first seal member and the second seal member in the step b).

15. The sealing method for use in the sensor element containment casing according to claim 13, wherein
the end portion is swaged simultaneously at the locations corresponding to the first seal member and the second seal member using a swaging jig bifurcated at a leading end thereof in the step b).

16. The sealing method for use in the sensor element containment casing according to claim 13, wherein
the first seal member is made of fluororubber, and
the second seal member is made of fluororesin.

17. The sealing method for use in the sensor element containment casing according to claim 16, wherein
the second seal member is made of PTFE.

18. The sealing method for use in the sensor element containment casing according to claim 13, wherein
an axial direction of the sensor element matches a direction of extension of the outer tube, and
a length of the second seal member in the direction of extension is equal to or greater than a length of the first seal member in the direction of extension.

19. The gas sensor according to claim 4, wherein
a side of the sealing portion has been swaged from outside at locations corresponding to the first seal member and the second seal member to seal the outer tube.

20. The sealing method for use in the sensor element containment casing according to claim 14, wherein
the end portion is swaged simultaneously at the locations corresponding to the first seal member and the second seal member using a swaging jig bifurcated at a leading end thereof in the step b).
